(19) United States
(12) Patent Application Publication
(10) Pub. No.: US 2026/0181768 A1
(43) Pub. Date: Jun. 25, 2026

(54) WIRING SUBSTRATE

(71) Applicant: SHINKO ELECTRIC INDUSTRIES CO., LTD., Nagano (JP)

(72) Inventor: Takuro KARAKIDA, Nagano (JP)

(21) Appl. No.: 19/425,131

(22) Filed: Dec. 18, 2025

(30) Foreign Application Priority Data
Dec. 24, 2024 (JP) 2024-227998

(51) Int. Cl. H05K 1/02; H05K 1/183

(52) U.S. Cl. CPC H05K 1/0298; H05K 1/183

(57) ABSTRACT

A wiring substrate includes a core layer, an electronic component in a cavity piercing through the core layer, an insulating layer covering the electronic component in the cavity, and a first wiring layer on a first surface of the core layer. The first wiring layer includes first ring-shaped wiring surrounding the cavity in a plan view. A first angle formed between the inner surface of the first ring-shaped wiring and the first surface of the core layer and a second angle, which is a supplementary angle of the angle formed between the first inner surface of the cavity connected to the first surface of the core layer and the first surface of the core layer, are acute angles in a cross-sectional view of the wiring substrate taken along a plane perpendicular to the first surface of the core layer. The first angle is greater than the second angle.

### CROSS-REFERENCE TO RELATED APPLICATION

This application is based upon and claims priority to Japanese Patent Application No. 2024-227998, filed on Dec. 24, 2024, the entire contents of which are incorporated herein by reference.

### FIELD

A certain aspect of the embodiment discussed herein is related to wiring substrates.

### BACKGROUND

A wiring substrate that accommodates an electronic component in an opening is known. According to such a wiring substrate, the gap between the electronic component and the inner wall of the opening is filled with resin. The resin, however, is less likely to enter the gap between the electronic component and the inner wall of the opening, which may result in poor filling due to insufficient resin. (See Japanese Laid-open Patent Publication No. 2023-155995.)

### SUMMARY

According to an aspect, a wiring substrate includes a core layer, an electronic component in a cavity piercing through the core layer, an insulating layer covering the electronic component in the cavity, and a first wiring layer on a first surface of the core layer. The first wiring layer includes first ring-shaped wiring surrounding the cavity in a plan view. A first angle formed between the inner surface of the first ring-shaped wiring and the first surface of the core layer and a second angle, which is a supplementary angle of the angle formed between the first inner surface of the cavity connected to the first surface of the core layer and the first surface of the core layer, are acute angles in a cross-sectional view of the wiring substrate taken along a plane perpendicular to the first surface of the core layer. The first angle is greater than the second angle.

The object and advantages of the invention will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF DRAWINGS

FIGS. 1A and 1B are diagrams illustrating a wiring substrate according to an embodiment;

FIGS. 2A through 2C are enlarged cross-sectional views of part of the periphery of a cavity of FIGS. 1A and 1B;

FIGS. 3A through 3G are diagrams illustrating a process of manufacturing a wiring substrate according to the embodiment;

FIGS. 4A and 4B are diagrams illustrating a wiring substrate according to a variety of the embodiment; and

FIG. 5 is an enlarged cross-sectional view of part of the periphery of a cavity of FIGS. 4A and 4B.

### DESCRIPTION OF EMBODIMENTS

According to an embodiment, a wiring substrate having an electronic component placed in a cavity is less likely to suffer from the cavity being filled with insufficient resin.

One or more embodiments of the present invention are described below with reference to the accompanying drawings. In the following, the same elements or components are referred to using the same reference numerals, and a description thereof may be omitted.

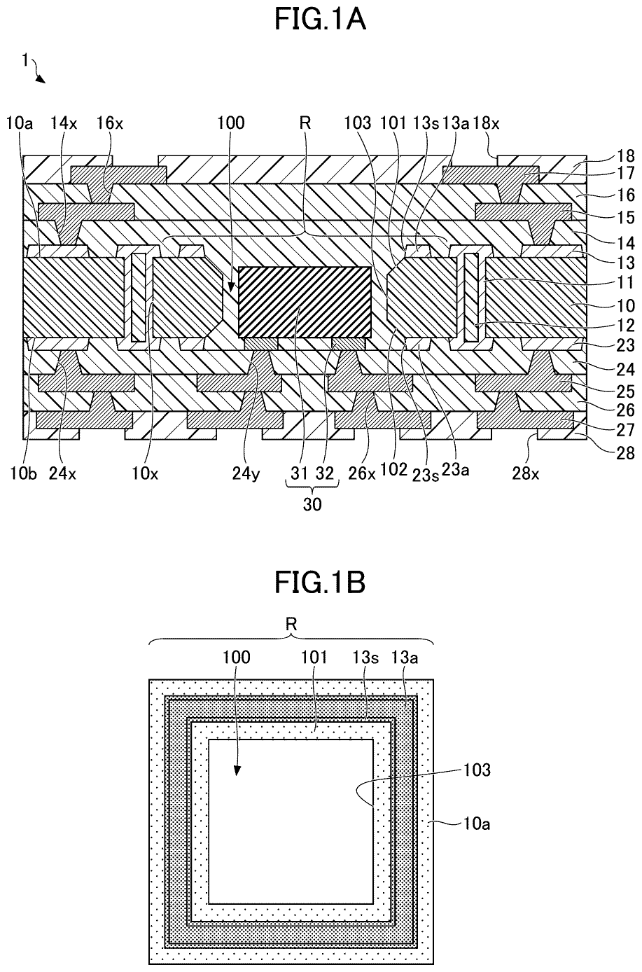

FIGS. 1A and 1B are diagrams illustrating a wiring substrate 1 according to an embodiment. FIG. 1A is a cross-sectional view of the wiring substrate 1, taken along a plane perpendicular to an upper surface 10a of a core layer 10. FIG. 1B is a plan view of a region R illustrated in FIG. 1A as seen from a direction normal to the upper surface 10a of the core layer 10. Referring to FIG. 1A, the wiring substrate 1 is a laminate of wiring layers and insulating layers stacked on each side of the core layer 10.

Specifically, according to the wiring substrate 1, a wiring layer 13, an insulating layer 14, a wiring layer 15, an insulating layer 16, a wiring layer 17, and a solder resist layer 18 are sequentially stacked on the upper surface 10a of the core layer 10. Furthermore, a wiring layer 23, an insulating layer 24, a wiring layer 25, an insulating layer 26, a wiring layer 27, and a solder resist layer 28 are sequentially stacked on a lower surface 10b of the core layer 10. The number of wiring layers and insulating layers stacked on the upper surface 10a and the lower surface 10b of the core layer 10 is not limited to that of the example illustrated in FIGS. 1A and 1B.

According to this embodiment, for convenience of description, the solder resist layer 18 side of the wiring substrate 1 is referred to as “upper side” or “first side,” and the solder resist layer 28 side of the wiring substrate 1 is referred to as “lower side” or “second side.” Furthermore, with respect to each part or element of the wiring substrate 1, a surface on the solder resist layer 18 side is referred to as “upper surface” or “first surface,” and a surface on the solder resist layer 28 side is referred to as “lower surface” or “second surface.” The wiring substrate 1, however, may be used in an inverted position or oriented at any angle. Furthermore, a plan view refers to a view of an object taken in a direction normal to the upper surface 10a of the core layer 10, and a planar shape refers to the shape of an object as viewed in a direction normal to the upper surface 10a of the core layer 10.

As the core layer 10, for example, a so-called glass epoxy substrate having glass cloth impregnated with insulating resin such as epoxy resin may be used. A substrate having a woven or non-woven fabric of glass fibers, carbon fibers, or aramid fibers impregnated with epoxy resin or the like may also be used as the core layer 10. The thickness of the core layer 10 is, for example, approximately 60 μm to approximately 1600 μm. Through holes 10x that pierce through the core layer 10 in its thickness direction are provided in the core layer 10. The planar shape of the through holes 10x is, for example, a circular shape.

A cavity 100 that pierces through the core layer 10 to expose the insulating layer 24 is formed in the core layer 10. The cavity 100 is defined by a first inner surface 101 connected to the upper surface 10a of the core layer 10, a second inner surface 102 connected to the lower surface 10b of the core layer 10, and a third inner surface 103 connecting the first inner surface 101 and the second inner surface 102. The third inner surface 103 is substantially perpendicular to the upper surface 10a of the core layer 10. The first inner surface 101 and the second inner surface 102 are inclined relative to the third inner surface 103.

An electronic component 30 is placed in the cavity 100. The electronic component 30 includes a body 31 and electrodes 32 formed on a surface (an electrode formation surface) of the body 31. The electronic component 30 is placed face-down in the cavity 100 with the electrodes 32 on the wiring layer 23 side. The gap between the side surface of the electronic component 30 and the third inner surface 103 of the cavity 100 is, for example, 50 μm to 300 μm.

The lower surfaces of the electrodes 32 of the electronic component 30 are, for example, flush with the lower surface of the wiring layer 23. The distance between the vertical position of the lower surface of the wiring layer 23 and the vertical position of the upper surface of the body 31 is smaller than the distance between the lower surface of the wiring layer 23 and the upper surface 10a of the core layer 10. The lower surface of the body 31 may be positioned closer to the wiring layer 25 than the lower surface 10b of the core layer 10.

The electronic component 30 may be either an active component or a passive component. Examples of the electronic component 30 include integrated passive devices (IPDs), semiconductor chips, capacitors, inductors, and resistors. The planar shape of the cavity 100 is, for example, similar to and is larger than the planar shape of the electronic component 30. The planar shape of the cavity 100 is, for example, a rectangular shape such as a square shape. More than one electronic component 30 may be placed in the cavity 100.

The wiring layer 13 is formed on the upper surface 10a of the core layer 10. The wiring layer 23 is formed on the lower surface 10b of the core layer 10. The wiring layer 13 and the wiring layer 23 are electrically connected by through vias 11 formed in the through holes 10x. According to the illustrated example, the through vias 11 have their respective internal spaces filled with resin bodies 12. The resin bodies 12, which are, for example, cylindrical in shape, have their respective upper ends projecting into the wiring layer 13 and have their respective lower ends projecting into the wiring layer 23. The resin bodies 12 are optional and may not be provided in the through vias 11. In this case, the through holes 10x are filled with the through vias 11 in their entirety.

The wiring layers 13 and 23 are patterned into respective predetermined planar shapes. For example, copper (Cu) may be used as a material for the wiring layers 13 and 23 and the through vias 11. The thickness of the wiring layers 13 and 23 is, for example, approximately 25 μm to approximately 45 μm. The wiring layers 13 and 23 and the through vias 11 may be formed as a one-piece structure.

The wiring layer 13 includes first ring-shaped wiring 13a surrounding the cavity 100 in a plan view. The term “ring-shaped” as used herein broadly refers to closed-loop shapes, which include, but are not limited to, circular, elliptical, polygonal, and rectangular frame shapes. According to this embodiment, an inner surface 13s of the first ring-shaped wiring 13a and the first inner surface 101 of the cavity 100 are in contact. When the cavity 100 is quadrangular (for example, rectangular) in a plan view, the first ring-shaped wiring 13a is, for example, frame-shaped in a plan view. The inner surface 13s of the first ring-shaped wiring 13a is not a surface perpendicular to but a surface inclined relative to the lower surface of the first ring-shaped wiring 13a. The outer surface of the first ring-shaped wiring 13a may be an inclined surface or a slope. The first ring-shaped wiring 13a may be floating, namely, not electrically connected to other wiring.

According to the example illustrated in FIGS. 1A and 1B, the wiring layer 23 includes second ring-shaped wiring 23a surrounding the cavity 100 in a plan view. An inner surface 23s of the second ring-shaped wiring 23a and the second inner surface 102 of the cavity 100 are in contact. When the cavity 100 is quadrangular in a plan view, the second ring-shaped wiring 23a is, for example, frame-shaped in a plan view. The inner surface 23s of the second ring-shaped wiring 23a is not a surface perpendicular to but a surface inclined relative to the lower surface of the second ring-shaped wiring 23a. The outer surface of the second ring-shaped wiring 23a may be an inclined surface or a slope. The second ring-shaped wiring 23a may be floating, namely, not electrically connected to other wiring. The second ring-shaped wiring 23a is optional and may not be included in the wiring layer 23.

The insulating layer 14 is formed on the upper surface 10a of the core layer 10 and covers the wiring layer 13. Furthermore, the insulating layer 14 enters the cavity 100 to cover the electronic component 30. The cavity 100 is filled with the insulating layer 14. That is, the insulating layer 14 is in contact with the inner surface 13s of the first ring-shaped wiring 13a, the first inner surface 101, the second inner surface 102, and the third inner surface 103 of the cavity 100, and the inner surface 23s of the second ring-shaped wiring 23a. Furthermore, the insulating layer 14 is also in contact with the upper surface and the side surface of the electronic component 30. The insulating layer 14 may extend from within the cavity 100 to an area lower than the lower surface 10b of the core layer 10. The insulating layer 14 may contact the lower surface of the electronic component 30.

For example, insulating resin whose main component is epoxy resin or polyimide resin may be used as a material for the insulating layer 14. The thickness of the insulating layer 14 on the upper surface 10a of the core layer 10 may be, for example, approximately 30 μm to approximately 40 μm. The insulating layer 14 may include filler such as silica (SiO₂).

Via holes 14x that pierce through the insulating layer 14 to expose the upper surface of the wiring layer 13 are provided in the insulating layer 14. The via holes 14x may be recesses having the shape of an inverted truncated cone, having an upper opening at the upper surface of the insulating layer 14 and a lower opening on the upper surface of the wiring layer 13. The upper opening is greater in diameter than the lower opening.

The wiring layer 15 is formed on the insulating layer 14. The wiring layer 15 includes via interconnects filling in the via holes 14x and a wiring pattern formed on the upper surface of the insulating layer 14. The wiring pattern is electrically connected to the wiring layer 13 via the via interconnects. The material and the thickness of the wiring pattern of the wiring layer 15 may be, for example, the same as those of the wiring layer 13.

The insulating layer 16 is so formed on the upper surface of the insulating layer 14 as to cover the wiring layer 15. The material and the thickness of the insulating layer 16 may be, for example, the same as those of the insulating layer 14. The insulating layer 16 may include filler such as silica (SiO₂).

Via holes 16x that pierce through the insulating layer 16 to expose the upper surface of the wiring layer 15 are provided in the insulating layer 16. The via holes 16x may be recesses having the shape of an inverted truncated cone, having an upper opening at the upper surface of the insulating layer 16 and a lower opening on the upper surface of the wiring layer 15. The upper opening is greater in diameter than the lower opening.

The wiring layer 17 is formed on the insulating layer 16. The wiring layer 17 includes via interconnects filling in the via holes 16x and a wiring pattern formed on the upper surface of the insulating layer 16. The wiring pattern is electrically connected to the wiring layer 15 via the via interconnects. The material and the thickness of the wiring pattern of the wiring layer 17 may be, for example, the same as those of the wiring layer 13.

The solder resist layer 18 is the upper-side outermost layer of the wiring substrate 1 and is a protective insulating layer so formed on the upper surface of the insulating layer 16 as to cover the wiring layer 17. The solder resist layer 18 may be formed of, for example, photosensitive epoxy insulating resin or acrylic insulating resin. The thickness of the solder resist layer 18 is, for example, approximately 15 μm to approximately 35 μm.

The solder resist layer 18 has openings 18x. The openings 18x pierce through the solder resist layer 18 to expose the upper surface of the wiring layer 17. The wiring layer 17 exposed in the openings 18x may be used as pads for electrical connections to an electronic component such as a semiconductor chip.

On the upper surface of the wiring layer 17 exposed in the openings 18x, a metal layer may be formed or an organic coating may be formed by anti-oxidation treatment such as an organic solderability preservative (OSP) process. Examples of metal layers include a gold (Au) layer, a Ni/Au layer (a laminated metal layer of a nickel (Ni) layer and a Au layer stacked in this order), a Ni/Pd/Au layer (a laminated metal layer of a Ni layer, a palladium (Pd) layer, and a Au layer stacked in this order), and a tin (Sn) layer.

The insulating layer 24 is formed on the lower surface 10b of the core layer 10 and covers the wiring layer 23. The insulating layer 24 is in contact with the lower surface of the insulating layer 14 positioned lower than the lower surface 10b of the core layer 10. The material and the thickness of the insulating layer 24 may be, for example, the same as those of the insulating layer 14. The insulating layer 24 may include filler such as silica (SiO₂).

Via holes 24x that pierce through the insulating layer 24 to expose the lower surface of the wiring layer 23 are provided in the insulating layer 24. Furthermore, via holes 24y that pierce through the insulating layer 24 to expose the lower surfaces of the electrodes 32 of the electronic component 30 are provided in the insulating layer 24. The via holes 24x and 24y may be recesses having the shape of a truncated cone, having a lower opening at the lower surface of the insulating layer 24 and an upper opening on the lower surface of the wiring layer 23 or the lower surface of the electrode 32. The lower opening is greater in diameter than the upper opening.

The wiring layer 25 is formed on the insulating layer 24. The wiring layer 25 includes via interconnects filling in the via holes 24x, via interconnects filling in the via holes 24y, and a wiring pattern formed on the lower surface of the insulating layer 24. Part of the wiring pattern is electrically connected to the wiring layer 23 via the via interconnects filling in the via holes 24x. Another part of the wiring pattern is electrically connected to the electrodes 32 via the via interconnects filling in the via holes 24y. The material and the thickness of the wiring pattern of the wiring layer 25 may be, for example, the same as those of the wiring layer 23.

The insulating layer 26 is so formed on the lower surface of the insulating layer 24 as to cover the wiring layer 25. The material and the thickness of the insulating layer 26 may be, for example, the same as those of the insulating layer 14. The insulating layer 26 may include filler such as silica (SiO₂).

Via holes 26x that pierce through the insulating layer 26 to expose the lower surface of the wiring layer 25 are provided in the insulating layer 26. The via holes 26x may be recesses having the shape of a truncated cone, having a lower opening at the lower surface of the insulating layer 26 and an upper opening on the lower surface of the wiring layer 25. The lower opening is greater in diameter than the upper opening.

The wiring layer 27 is formed on the insulating layer 26. The wiring layer 27 includes via interconnects filling in the via holes 26x and a wiring pattern formed on the lower surface of the insulating layer 26. The wiring pattern is electrically connected to the wiring layer 25 via the via interconnects. The material and the thickness of the wiring pattern of the wiring layer 27 may be, for example, the same as those of the wiring layer 23.

The solder resist layer 28 is the lower-side outermost layer of the wiring substrate 1 and is a protective insulating layer so formed on the lower surface of the insulating layer 26 as to cover the wiring layer 27. The material and the thickness of the solder resist layer 28 may be, for example, the same as those of the solder resist layer 18. The solder resist layer 28 has openings 28x. Part of the lower surface of the wiring layer 27 is exposed in the openings 28x. The planar shape of the openings 28x may be, for example, a circular shape. The wiring layer 27 exposed in the openings 28x may be used as pads for electrical connections to a mounting substrate such as a motherboard. On the lower surface of the wiring layer 27 exposed in the openings 28x, the above-described metal layer may be formed or anti-oxidation treatment such as an OSP process may be performed on an as-needed basis.

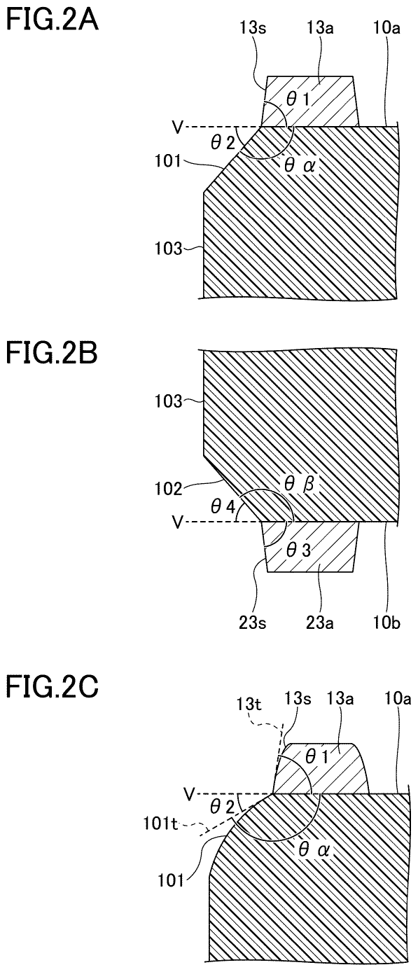

FIGS. 2A through 2C are enlarged cross-sectional views of part of the periphery of the cavity 100 illustrated in FIGS. 1A and 1B. In FIGS. 2A and 2C, V indicates a virtual straight line that is an extension of the upper surface 10a of the core layer 10 in a cross-sectional view. In FIG. 2B, V indicates a virtual straight line that is an extension of the lower surface 10b of the core layer 10 in a cross-sectional view.

As illustrated in FIG. 2A, in a cross-sectional view, a first angle θ1 formed between the inner surface 13s of the first ring-shaped wiring 13a and the upper surface 10a of the core layer 10 and a second angle θ2, which is the supplementary angle of an angle θα formed between the first inner surface 101 of the cavity 100 and the upper surface 10a of the core layer 10, are both acute angles. The first angle θ1 is greater than the second angle θ2. The first angle θ1 is, for example, 70 degrees or more and 80 degrees or less. The second angle θ2 is, for example, 65 degrees or more and 70 degrees or less.

As illustrated in FIG. 2B, in a cross-sectional view, a third angle θ3 formed between the inner surface 23s of the second ring-shaped wiring 23a and the lower surface 10b of the core layer 10 and a fourth angle θ4, which is the supplementary angle of an angle θβ formed between the second inner surface 102 of the cavity 100 and the lower surface 10b of the core layer 10, are both acute angles. The third angle θ3 is greater than the fourth angle θ4. The third angle θ3 is, for example, 70 degrees or more and 80 degrees or less. The fourth angle θ4 is, for example, 65 degrees or more and 70 degrees or less. The inner surface 23s of the second ring-shaped wiring 23a and the second inner surface 102 of the cavity 100 are substantially an inverted mirror image of the inner surface 13s of the first ring-shaped wiring 13a and the first inner surface 101 of the cavity 100.

As illustrated in FIG. 2C, when the inner surface 13s of the first ring-shaped wiring 13a is not a straight line, the angle formed between the upper surface 10a and a tangent line 13t at the intersection of the inner surface 13s and the upper surface 10a is determined as the first angle θ1 in a cross-sectional view. Furthermore, when the first inner surface 101 of the cavity 100 is not a straight line, the angle formed between the upper surface 10a and a tangent line 101t at the intersection of the first inner surface 101 and the upper surface 10a is determined as the angle θα and the supplementary angle of the angle θα is determined as the second angle θ2 in a cross-sectional view. The same is the case with when the inner surface 23s of the second ring-shaped wiring 23a is not a straight line and when the second inner surface 102 of the cavity 100 is not a straight line.

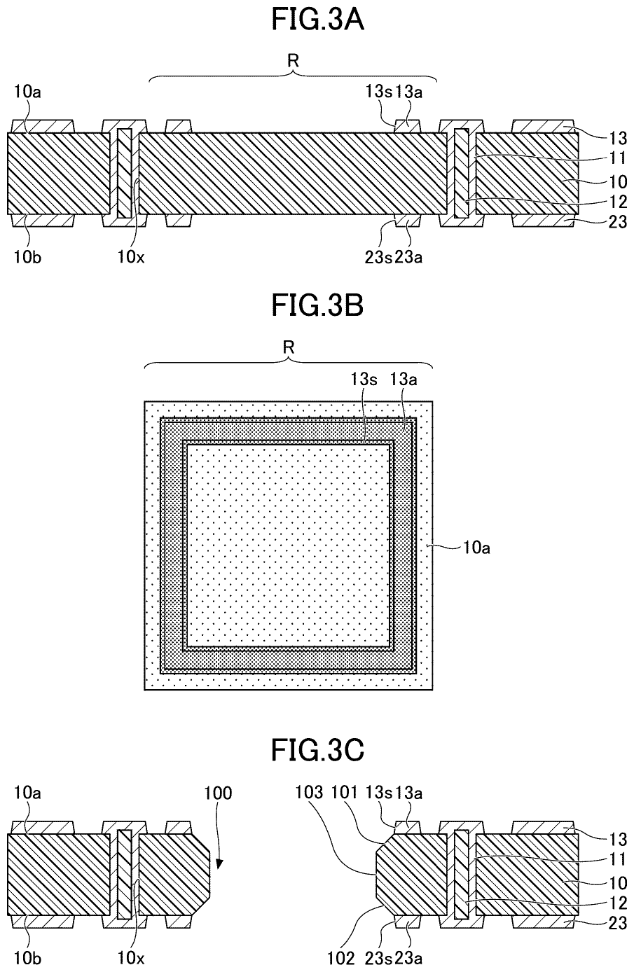

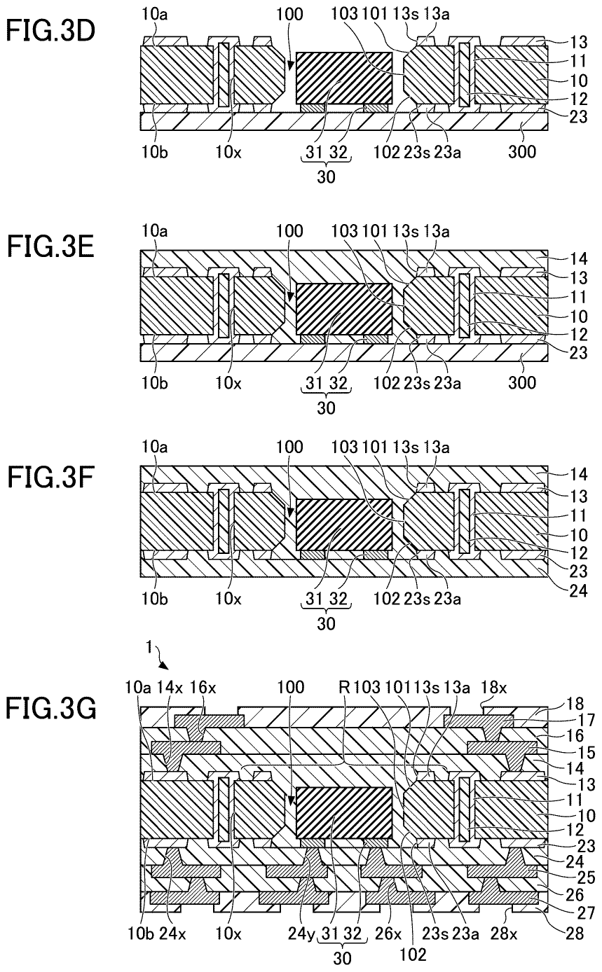

Next, a method of manufacturing a wiring substrate is described. FIGS. 3A through 3G are diagrams illustrating a process of manufacturing a wiring substrate according to this embodiment. FIGS. 3A and 3C through 3G are cross-sectional views corresponding to FIG. 1A. FIG. 3B is a plan view of the region R illustrated in FIG. 3A as seen from a direction normal to the upper surface 10a of the core layer 10. Here, by way of example, a process of manufacturing a single wiring substrate is illustrated, but multiple parts to become wiring substrates may be manufactured and thereafter be separated into multiple wiring substrates.

First, in the process illustrated in FIGS. 3A and 3B, the core layer 10 having the wiring layer 13 on the upper surface 10a, the wiring layer 23 on the lower surface 10b, and the through vias 11 and the resin bodies 12 in the through holes 10x is prepared. Specifically, for example, a laminate having unpatterned plain copper foil formed on each of the upper surface 10a and the lower surface 10b of the core layer 10, which is a so-called glass epoxy substrate or the like, is prepared. The through holes 10x piercing through the core layer 10 and the copper foil on each surface are formed in the prepared laminate by laser processing using a CO₂ laser or the like. A desmear process may be performed on an as-needed basis to remove the smear of resin included in the core layer 10, attached to the inner surfaces of the through holes 10x.

Next, a seed layer (copper or the like) covering the copper foil on each surface and the inner surfaces of the through holes 10x is formed by, for example, electroless plating, sputtering, or the like. Then, an electroplating layer (copper or the like) is formed on the seed layer by electroplating using the seed layer as a power feed layer. At this point, through holes are formed in the electroplating layer. These through holes are filled with epoxy resin or the like to form the resin bodies 12. As a result, the through holes 10x are filled with the electroplating layer formed on the seed layer to form the through vias 11, and the resin bodies 12 are formed inside the through vias 11. A metal layer formed of copper or the like is formed over the through vias 11 and the resin bodies 12 on each side by electroless plating and electroplating. The wiring layers 13 and 23, which are laminates of the copper foil, the seed layer, the electroplating layer, and the metal layer, are formed on the upper surface 10a and the lower surface 10b, respectively, of the core layer 10. Next, the wiring layers 13 and 23 are patterned into predetermined planar shapes by a subtractive process. At this point, along with wiring patterns, the first ring-shaped wiring 13a and the second ring-shaped wiring 23a as well are formed. The inner surface 13s of the first ring-shaped wiring 13a and the inner surface 23s of the second ring-shaped wiring 23a, which are formed by a subtractive process, are inclined surfaces. The side surfaces of the wiring patterns as well are inclined surfaces. The inclination angles are as described above with reference to FIGS. 2A through 2C.

Next, in the process illustrated in FIG. 3C, the cavity 100 piercing through the core layer 10 from the upper surface 10a to the lower surface 10b is formed. The cavity 100 may be formed by laser processing. A desmear process is performed under a predetermined temperature condition on an as-needed basis to remove the smear of resin included in the core layer 10, attached to the inner surface of the cavity 100. Ultrasonic cleaning may be performed after the desmear process.

In the case of forming the cavity 100 by laser processing, first, laser light is emitted onto the upper surface 10a of the core layer 10 along the bottom end (edge) of the inner surface 13s of the first ring-shaped wiring 13a from the upper surface 10a side of the core layer 10. The laser light is emitted until an opening is formed up to approximately the half of the core layer 10 in its thickness direction from the upper surface 10a of the core layer 10.

Next, laser light is emitted onto the lower surface 10b of the core layer 10 along the bottom end (edge) of the inner surface 23s of the second ring-shaped wiring 23a from the lower surface 10b side of the core layer 10. The laser light is emitted until an opening formed from the lower surface 10b side of the core layer 10 communicates with the opening formed from the upper surface 10a side of the core layer 10.

As a result, part of the core layer 10 is removed, so that the cavity 100 of the shape illustrated in FIG. 1B is formed. By controlling laser emission conditions such as the intensity of laser light and the emission angle of laser light at the time of laser light emission, the first inner surface 101 and the second inner surface 102 of the cavity 100 can be formed with the angles illustrated with reference to FIGS. 2A through 2C.

Next, in the process illustrated in FIG. 3D, the electronic component 30 is placed in the cavity 100. Specifically, first, the lower surface of the wiring layer 23 is laminated with a support film 300 in such a manner as to cover the cavity 100. For example, a low-tack resin film may be used as the support film 300. Next, the electronic component 30 having the electrodes 32 is placed face-down on the upper surface of the support film 300 exposed in the cavity 100. For example, a mounter for electronic components may be used to place the electronic component 30.

Next, in the process illustrated in FIG. 3E, the insulating layer 14, which covers the electronic component 30 in the cavity 100 and extends onto the upper surface 10a of the core layer 10 from within the cavity 100 to cover the upper surface and the side surface of the wiring layer 13, is formed. The insulating layer 14 extends to an area lower than the lower surface 10b of the core layer 10 from within the cavity 100.

Specifically, for example, the upper surface 10a of the core layer 10 is laminated with a semi-cured film of epoxy resin or the like (hereinafter, “epoxy resin film”) in such a manner as to cover the wiring layer 13. Then, while heating the epoxy resin film, the epoxy resin film is pressed toward the core layer 10 using a vacuum laminator or the like. As a result, the softened epoxy resin film enters the cavity 100 to fill in the cavity 100 in such a manner as to cover the electronic component 30. Thereafter, the epoxy resin film is cured into the insulating layer 14. Instead of laminating the upper surface 10a of the core layer 10 with the epoxy resin film, epoxy resin or the like in liquid or paste form may be applied onto the upper surface 10a of the core layer 10 and thereafter be cured into the insulating layer 14.

The insulating layer formed on the upper surface 10a of the core layer 10 and the insulating layer covering the electronic component 30 within the cavity 100 may be separate bodies. In this case, the insulating layer covering the electronic component 30 within the cavity 100 is formed first, and the other insulating layer is thereafter formed on the upper surface 10a of the core layer 10.

Next, in the process illustrated in FIG. 3F, after the removal of the support film 300, the insulating layer 24 that covers the wiring layer 23 is formed on the lower surface 10b of the core layer 10. The same as the insulating layer 14, the insulating layer 24 may be formed using a film of epoxy resin or the like or epoxy resin or the like in liquid or paste form.

Next, in the process illustrated in FIG. 3G, the remaining layers are sequentially stacked. First, the wiring layers 15 and 25 are formed. Specifically, the via holes 14x that pierce through the insulating layer 14 to expose the upper surface of the wiring layer 13 are formed in the insulating layer 14. Furthermore, the via holes 24x that pierce through the insulating layer 24 to expose the lower surface of the wiring layer 23 and the via holes 24y piercing through the insulating layer 24 to expose the lower surfaces of the electrodes 32 of the electronic component 30 are formed in the insulating layer 24. The via holes 14x, 24x and 24y may be formed by, for example, laser processing using a CO₂ laser or the like. Preferably, after the formation of the via holes 14x, 24x and 24y, a desmear process is performed to remove resin smear attached to the surface of the wiring layer 13, the surface of the wiring layer 23, and the surfaces of the electrodes 32 exposed at the bottom of the via holes 14x, 24x and 24y, respectively.

Next, the wiring layer 15 is formed on the insulating layer 14. The wiring layer 15 includes the via interconnects filling in the via holes 14x and the wiring pattern formed on the upper surface of the insulating layer 14. The wiring layer 15 is electrically connected to the wiring layer 13 exposed at the bottom of the via holes 14x.

Furthermore, the wiring layer 25 is formed on the insulating layer 24. The wiring layer 25 includes the via interconnects filling in the via holes 24x, the via interconnects filling in the via holes 24y, and the wiring pattern formed on the lower surface of the insulating layer 24. Part of the wiring pattern is electrically connected to the wiring layer 23 via the via interconnects filling in the via holes 24x. Another part of the wiring pattern is electrically connected to the electrodes 32 via the via interconnects filling in the via holes 24y.

The wiring layers 15 and 25 may be formed using a wiring formation process among various wiring formation processes, such as a semi-additive process or a subtractive process. For example, in the case of forming the wiring layer 15 using a semi-additive process, a seed layer is formed on the surface of the insulating layer 14 including the inner walls of the via holes 14x and the surface of the wiring layer 13 exposed in the via holes 14x by electroless plating of copper. Next, a plating resist pattern having openings according to the shape of the wiring pattern of the wiring layer 15 is formed on the seed layer, and an electroplating layer is deposited on the seed layer exposed in the openings of the plating resist pattern by electroplating of copper feeding power from the seed layer. Next, the plating resist pattern is removed. Then, the seed layer exposed from the electroplating layer is removed by etching using the electroplating layer as a mask, so that the wiring layer 15 including the via interconnects and the wiring pattern is formed. The wiring layer 25 may be formed in the same manner.

Next, the insulating layer 16 is so formed on the upper surface of the insulating layer 14 as to cover the wiring layer 15. Furthermore, the insulating layer 26 is so formed on the lower surface of the insulating layer 24 as to cover the wiring layer 25. The insulating layers 16 and 26 may be formed in the same manner as the insulating layer 14, for example. Next, the wiring layer 17 is formed on the insulating layer 16 and the wiring layer 27 is formed on the insulating layer 26. The wiring layers 17 and 27 may be formed in the same manner as the wiring layer 15, for example.

Next, the solder resist layer 18 is so formed on the upper surface of the insulating layer 16 as to cover the wiring layer 17. Furthermore, the solder resist layer 28 is so formed on the lower surface of the insulating layer 26 as to cover the wiring layer 27. The solder resist layer 18 may be formed by, for example, applying photosensitive epoxy insulating resin or acrylic insulating resin in liquid or paste form on the upper surface of the insulating layer 16 in such a manner as to cover the wiring layer 17 by screen printing, roll coating, spin coating or the like. Alternatively, the solder resist layer 18 may be formed by, for example, laminating the upper surface of the insulating layer 16 with a film of photosensitive epoxy insulating resin or acrylic insulating resin in such a manner as to cover the wiring layer 17. The solder resist layer 28 may be formed in the same manner as the solder resist layer 18.

Next, the solder resist layers 18 and 28 are exposed to light and developed to form the openings 18x that expose part of the upper surface of the wiring layer 17 in the solder resist layer 18 (photolithography) and form the openings 28x that expose part of the upper surface of the wiring layer 27 in the solder resist layer 28 (photolithography). The planar shapes of the openings 18x and 28x may be, for example, circular shapes. The diameters of the openings 18x and 28x may be designed as desired in accordance with objects to be connected (such as semiconductor chips and motherboards).

In this process, the above-described metal layer may be formed on the upper surface of the wiring layer 17 exposed at the bottom of the openings 18x and the lower surface of the wiring layer 27 exposed at the bottom of the openings 28x by, for example, electroless plating or the like. Instead of forming the metal layer, anti-oxidation treatment such as an OSP process may be performed. By the above-described process, the wiring substrate 1 is completed.

Thus, according to the wiring substrate 1, in a cross-sectional view taken along a plane perpendicular to the upper surface 10a of the core layer 10, the first angle θ1 and the second angle θ2 are both acute angles. That is, the inner surface 13s of the first ring-shaped wiring 13a and the first inner surface 101 of the cavity 100 are not perpendicular to but are inclined relative to the upper surface 10a of the core layer 10. Therefore, when the insulating layer 14 that covers the electronic component 30 in the cavity 100 is formed in the process illustrated in FIG. 3E, the flow of resin to become the insulating layer 14 into the cavity 100 is accelerated, so that poor filling of resin is less likely to occur. As a result, it is possible to reduce voids due to poor filling of resin.

Furthermore, the second angle θ2 is smaller than the first angle θ1. Therefore, when the insulating layer 14 that covers the electronic component 30 in the cavity 100 is formed in the process illustrated in FIG. 3E, resin to become the insulating layer 14 is prevented from rushing into the cavity 100 all at once. This makes it possible to prevent turning of the electronic component 30 due to a sudden rush of resin.

Furthermore, the first angle θ1 is greater than the second angle θ2. Therefore, the inclination changes at the line of contact between the inner surface 13s of the first ring-shaped wiring 13a and the first inner surface 101 of the cavity 100, and the insulating layer 14 engages with the part where the inclination changes. Therefore, compared with the case where the first angle θ1 and the second angle θ2 are equal, the adhesion between the core layer 10 and the insulating layer 14 can increase. The same is the case with the core layer 10 and the insulating layer 24.

Next, a variation of the above-described embodiment is described. According to the variation, a wiring substrate whose cavity is different in shape from the cavity 100 of the above-described embodiment is illustrated. In the following, a description of the same elements or components as those of the above-described embodiment may be omitted.

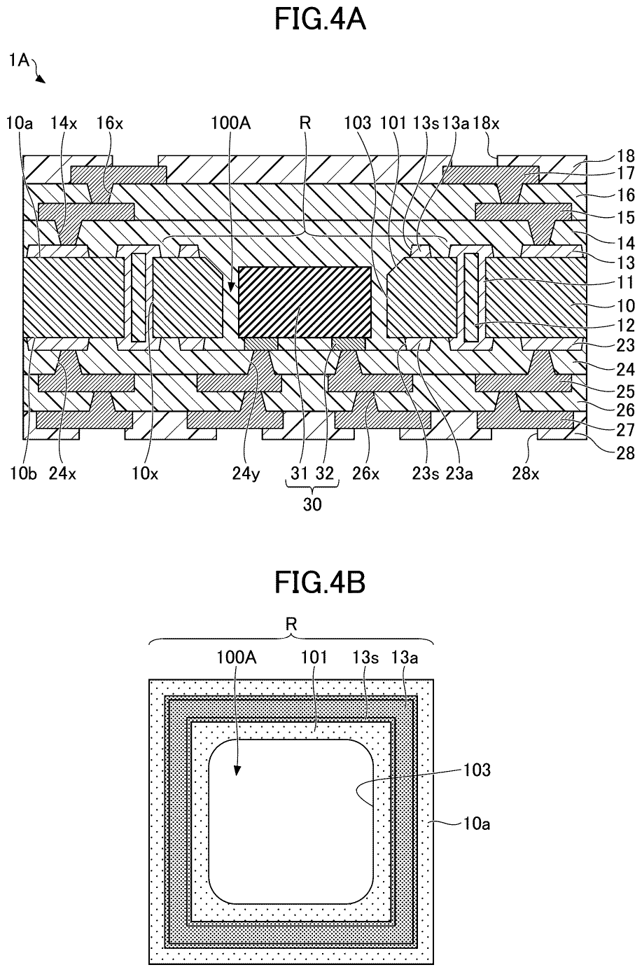

FIGS. 4A and 4B are diagrams illustrating a wiring substrate 1A according to the variation. FIG. 4A is a cross-sectional view of the wiring substrate 1A, taken along a plane perpendicular to the upper surface 10a of the core layer 10. FIG. 4B is a plan view of the region R illustrated in FIG. 4A as seen from a direction normal to the upper surface 10a of the core layer 10.

Referring to FIGS. 4A and 4B, the wiring substrate 1A is different from the wiring substrate 1 in that the cavity 100 is replaced with a cavity 100A. The cavity 100A includes the first inner surface 101 connected to the upper surface 10a of the core layer 10 and the third inner surface 103 connecting the first inner surface 101 and the lower surface 10b of the core layer 10. The cavity 100A is devoid of a surface corresponding to the second inner surface 102 of the cavity 100. The third inner surface 103 is substantially perpendicular to the upper surface 10a of the core layer 10. The first inner surface 101 is inclined relative to the third inner surface 103.

Furthermore, while the inner surface 13s of the first ring-shaped wiring 13a and the first inner surface 101 of the cavity 100 are in contact according to the wiring substrate 1, the inner surface 13s and the first inner surface 101 are out of contact according to the wiring substrate 1A. According to the wiring substrate 1A, the inner surface 13s of the first ring-shaped wiring 13a and the first inner surface 101 of the cavity 100A are adjacent to each other across part of the upper surface 10a of the core layer 10.

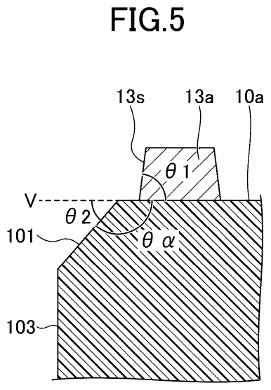

FIG. 5 is an enlarged cross-sectional view of part of the periphery of the cavity 100A illustrated in FIGS. 4A and 4B. As illustrated in FIG. 5, the relationship between the first angle θ1 and the second angle θ2 is the same as that illustrated in FIG. 2A. That is, the first angle θ1 formed between the inner surface 13s of the first ring-shaped wiring 13a and the upper surface 10a of the core layer 10 and the second angle θ2, which is the supplementary angle of the angle θα formed between the first inner surface 101 of the cavity 100A and the upper surface 10a of the core layer 10, are both acute angles. The first angle θ1 is greater than the second angle θ2. The first angle θ1 is, for example, 70 degrees or more and 80 degrees or less. The second angle θ2 is, for example, 65 degrees or more and 70 degrees or less.

The cavity 100A may be formed by router processing. The second angle θ2 may be controlled by, for example, the bit diameter and the bit angle of a router. Unlike laser processing, router processing has difficulty in forming the first inner surface 101 by processing the very bottom edge of the inner surface 13s of the first ring-shaped wiring 13a. Therefore, the first inner surface 101 of the cavity 100A and the inner surface 13s of the first ring-shaped wiring 13a are so shaped as to be adjacent to each other across part of the upper surface 10a of the core layer 10. Furthermore, the planar shape of the cavity 100A formed by router processing is a rectangular shape with rounded corners.

Thus, the cavity may be either formed by laser processing or formed by router processing. In the case of forming the cavity by router processing as well, the first angle θ1 and the second angle θ2 can be both acute angles and the first angle θ1 can be greater than the second angle θ2 in a cross-sectional view taken along a plane perpendicular to the upper surface 10a of the core layer 10. As a result, the same effects as those of the above-described embodiment are produced.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority or inferiority of the invention. Although one or more embodiments of the present invention have been described in detail, it should be understood that the various changes, substitutions, and alterations could be made hereto without departing from the spirit and scope of the invention.

What is claimed is:

1. A wiring substrate comprising:
a core layer;
an electronic component in a cavity piercing through the core layer;
an insulating layer covering the electronic component in the cavity; and
a first wiring layer on a first surface of the core layer, the first wiring layer including first ring-shaped wiring surrounding the cavity in a plan view,
wherein each of a first angle and a second angle is an acute angle in a cross-sectional view of the wiring substrate taken along a plane perpendicular to the first surface of the core layer, the first angle being formed between an inner surface of the first ring-shaped wiring and the first surface of the core layer, the second angle being a supplementary angle of an angle formed between a first inner surface of the cavity connected to the first surface of the core layer and the first surface of the core layer, the first angle being greater than the second angle.

2. The wiring substrate as claimed in claim 1, further comprising:
a second wiring layer on a second surface of the core layer on an opposite side from the first surface, the second wiring layer including second ring-shaped wiring surrounding the cavity in a plan view,
wherein each of a third angle and a fourth angle is an acute angle in the cross-sectional view of the wiring substrate taken along the plane perpendicular to the first surface of the core layer, the third angle being formed between an inner surface of the second ring-shaped wiring and the second surface of the core layer, the fourth angle being a supplementary angle of an angle formed between a second inner surface of the cavity connected to the second surface of the core layer and the second surface of the core layer, the third angle being greater than the fourth angle.

3. The wiring substrate as claimed in claim 2, wherein the insulating layer is in contact with the inner surface of the first ring-shaped wiring, the first inner surface of the cavity, the second inner surface of the cavity, and the inner surface of the second ring-shaped wiring.

4. The wiring substrate as claimed in claim 1, wherein the inner surface of the first ring-shaped wiring and the first inner surface of the cavity are in contact with each other.

5. The wiring substrate as claimed in claim 1, wherein the inner surface of the first ring-shaped wiring and the first inner surface of the cavity are adjacent to each other across a part of the first surface of the core layer.

6. The wiring substrate as claimed in claim 1, wherein the first angle is 70 degrees or more and 80 degrees or less.

7. The wiring substrate as claimed in claim 1, wherein the second angle is 65 degrees or more and 70 degrees or less.

8. The wiring substrate as claimed in claim 1, wherein a planar shape of the cavity is similar to and is larger than a planar shape of the electronic component.

9. The wiring substrate as claimed in claim 1, wherein
a planar shape of the cavity is a rectangular shape, and
a planar shape of the first ring-shaped wiring is a frame shape.

10. The wiring substrate as claimed in claim 1, wherein the electronic component includes a body and an electrode on an electrode formation surface of the body, the electronic component being placed face-down in the cavity.

11. The wiring substrate as claimed in claim 10, further comprising:
a second wiring layer on a second surface of the core layer on an opposite side from the first surface,
wherein a surface of the electrode facing away from the electrode formation surface of the body is flush with a surface of the second wiring layer facing away from the second surface of the core layer.

12. The wiring substrate as claimed in claim 11, wherein a distance between the surface of the electrode and a surface of the body on an opposite side of the electrode formation surface is smaller than a distance between the surface of the second wiring layer and the first surface of the core layer.

13. The wiring substrate as claimed in claim 10, wherein the insulating layer extends onto the electrode formation surface of the body of the electronic component from within the cavity.
